(19) United States
(12) Patent Application Publication
(10) Pub. No.: US 2005/0014378 A1
(43) Pub. Date: Jan. 20, 2005

(54) Substrate patterning integration

(76) Inventors: Michael D. Goodner, Hillsboro, OR (US); Bob E. Leet, Scottsdale, AZ (US); Robert P. Meagley, Hillsboro, OR (US); Michael McSwiney, Hillsboro, OR (US)

Correspondence Address: Michael A. Bernadicou;BLAKELY, SOKOLOFF, TAYLOR & ZAFMAN LLP, Seventh Floor, 12400 Wilshire Boulevard, Los Angeles, CA, 90025, US

(21) Appl. No.: 10/621,744

(22) Filed: Jul. 16, 2003

(51) Int. Cl. H01L 21/311

(52) U.S. Cl. 438/700; 438/702

(57) ABSTRACT

A substrate patterning integration is disclosed to address structural and process limitations of conventional resist patterning over hardmask techniques. A resist layer positioned adjacent a substrate layer is patterned, subsequent to which a hardmask layer is deposited. The hardmask layer may be thinned to expose remaining portions of the patterned resist layer for removal by chemical treatment to expose portions of the underlying substrate layer into which the pattern may be transferred using wet or dry chemical etch techniques.

### BACKGROUND OF THE INVENTION

Microelectronic structures, such as semiconductor structures, may be created by forming layers and trenches in various structural configurations from various materials. One of the challenges associated with conventional substrate patterning techniques is the detrimental damage of adjacent materials when exposed to solvents or decomposing chemistries targeted at a particular material to be trenched. Unwanted damage may, for example, manifest as substrate attack by resist stripping solvent, photoresist poisoning and unwanted optical property modification, line edge roughness and trench “footing” or “shelling”, and top rounding of resist profiles.

Referring to FIGS. 1A-1E, a conventional substrate patterning scenario is depicted in cross sectional views. Referring to FIG. 1A, a substrate layer (100) is shown adjacent a hardmask layer (102) and resist layer (104). The term “hardmask” is generally used in reference to a protective layer for the underlying substrate layer (100) and having etch properties different from those of the associated resist layer (104) to enable patterning of the resist layer (104) material while controlling damage to the underlying substrate layer (100) material. Two categories of hardmask materials are commonly utilized in semiconductor processing: chemical-vapor-deposited (CVD) hardmask materials, such as CVD silicon dioxide, CVD silicon nitride, CVD silicon oxynitride, and CVD silicon carbide, and spin-on, or spin-coat, deposited hardmask materials, such as spin-on glasses (e.g., Accuglass™, manufactured by Honeywell Electronic Materials, and OCD™, manufactured by Tokyo Ohka Kogyo) and spin-on organics (e.g. ENSEMBLE™ and ENSEMBLE™ ES manufactured by Dow Chemical). As depicted in FIG. 1A, in a conventional process flow, the hardmask layer (102) is deposited adjacent the substrate layer (100) before the resist layer (104) is deposited. Many potential candidate CVD hardmask materials are not well suited for use in substrate patterning due to substrate sensitivities, such as temperature processing requirements or mechanical requirements with some fragile polymer-based substrates. In addition, some hardmask materials preclude the introduction of some resist materials due to unwanted hardmask-resist interaction problems, such as resist poisoning and poor adhesion.

Referring to FIG. 1B, in a conventional patterning process, trenches (106, 108) are formed into the resist layer (104) typically by introducing wet chemical etchants selective to the resist layer (104) material, as opposed to the underlying hardmask layer (102) material. Boundary effects such as resist “footing” may preclude complete etching to form regular trenches such as those depicted (106, 108) due to sub-threshold irradiation exposure inadequately developing lower portions of the resist layer (104) during patterning treatments, or resist poisoning in the lower portions of the resist layer (104) due to adjacently positioned materials. With subsequent treatments, resist layer (104) footing may result in incomplete hardmask removal at the edges of the features. Such challenges with resist layer (104) trenching have been addressed with pH modification protocols; but such fixes have been correlated with other undesirable performance problems. The trenches may be extended or deepened (110, 112) with the introduction of etch chemistries selective to the hardmask layer (102) material, and not particularly selective to the patterned resist layer (104) material, as depicted in FIG. 1C. One of the challenges with conventional treatments at such a stage of substrate patterning is the formation of a residue or “crust” from decomposed hardmask material, which may form unwanted irregular structures in and around the trenches (defects known by names such as “shells”, “craters”, “microtrenching”, or “veils”). Referring to FIG. 1D, the trenches may be further deepened (114, 116) by introducing wet or dry etch chemistries configured to controllably remove substrate layer (102) material without substantial modification of the associated hardmask (102) material. The remaining photoresist (104) may be removed prior to or subsequent to deepening the trenches (114, 116). Finally, remaining portions of the hardmask (102) and resist (104) layers may be removed using chemical and/or chemical-mechanical techniques to yield a patterned (118) substrate layer (100), such as that depicted in FIG. 1E.

Referring to FIG. 2, a conventional substrate patterning process flow, like that depicted in cross-sectional views in FIGS. 1A-1E, is summarized in flow chart form. After the hardmask layer is formed (200) upon the substrate, a resist layer may be formed (202) upon the hardmask layer, subsequent to which the resist layer may be patterned (204) to provide access for transferring (206) the pattern into the underlying hardmask layer. Remaining resist material may then be removed (208), followed by transfer (210) of the pattern into the substrate and removal (212) of remaining hardmask material along with any remaining resist material not removed previously. As discussed above, conventional patterning process flows such as this are associated with undesirable materials selection and processing limitations.

There is a need to address the shortcomings of conventional substrate patterning techniques such as those described above.

### BRIEF DESCRIPTION OF THE DRAWINGS

The present invention is illustrated by way of example and is not limited in the figures of the accompanying drawings, in which like references indicate similar elements. Features shown in the drawings are not intended to be drawn to scale, nor are they intended to be shown in precise positional relationship.

FIGS. 1A-1E are cross-sectional depictions of conventional substrate patterning treatment.

FIG. 2 is a flowchart depicting various stages of a conventional substrate patterning treatment.

FIGS. 3A-3G are cross-sectional views of various aspects of one embodiment of a substrate patterning treatment of the present invention.

FIG. 4 is a flowchart depicting various stages of one embodiment of a substrate patterning treatment of the present invention.

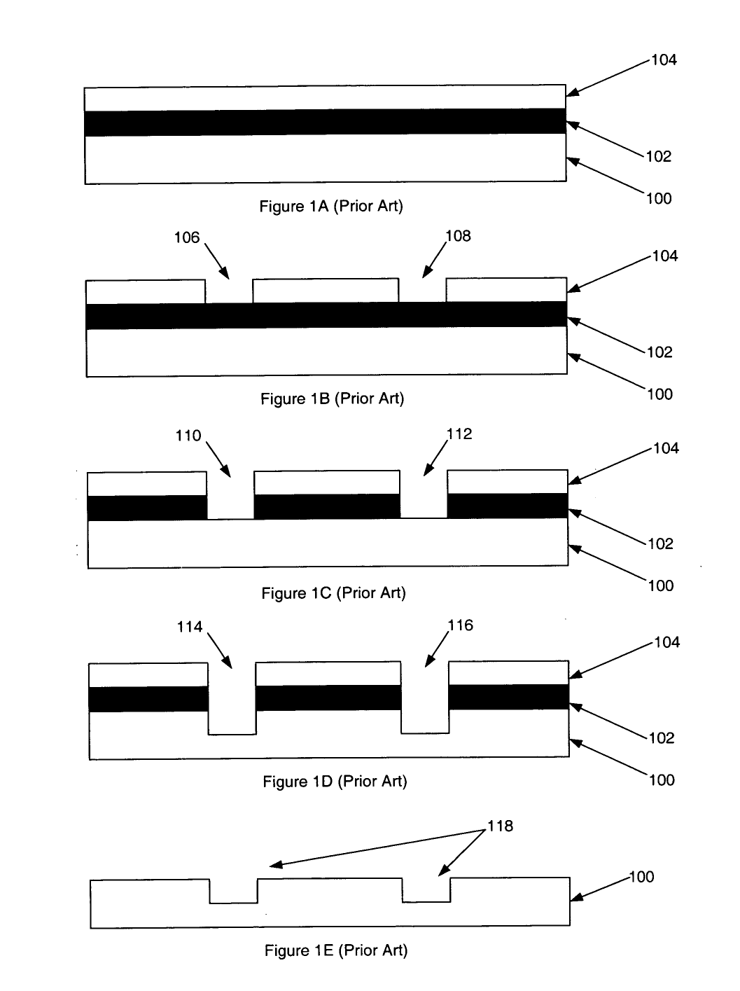

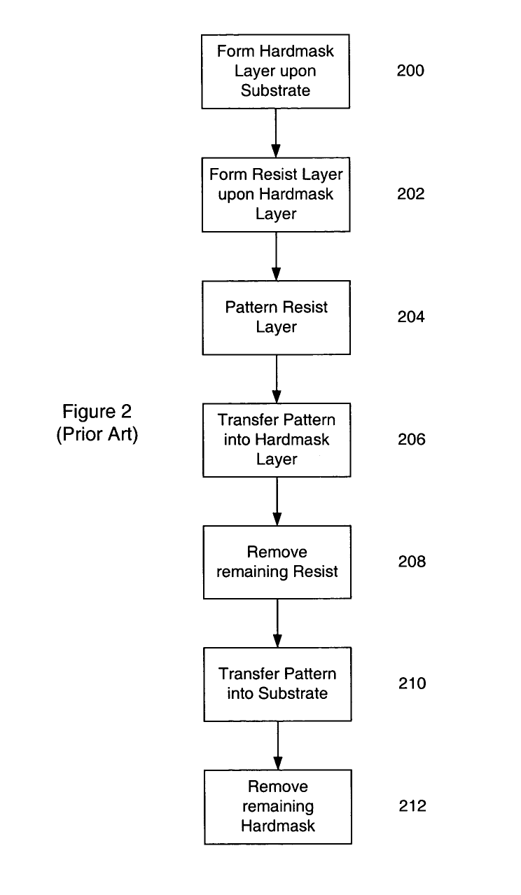

### DETAILED DESCRIPTION

In the following detailed description of embodiments of the invention, reference is made to the accompanying drawings in which like references indicate similar elements. The illustrative embodiments described herein are disclosed in sufficient detail to enable those skilled in the art to practice the invention. The following detailed description is therefore not to be taken in a limiting sense, and the scope of the invention is defined only by the appended claims.

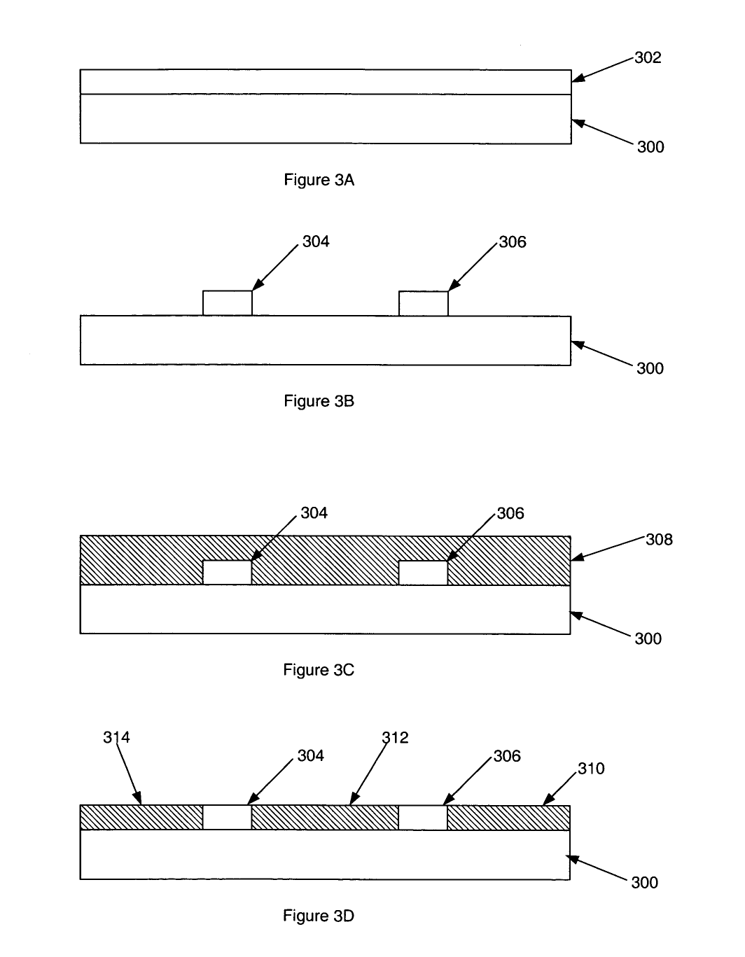

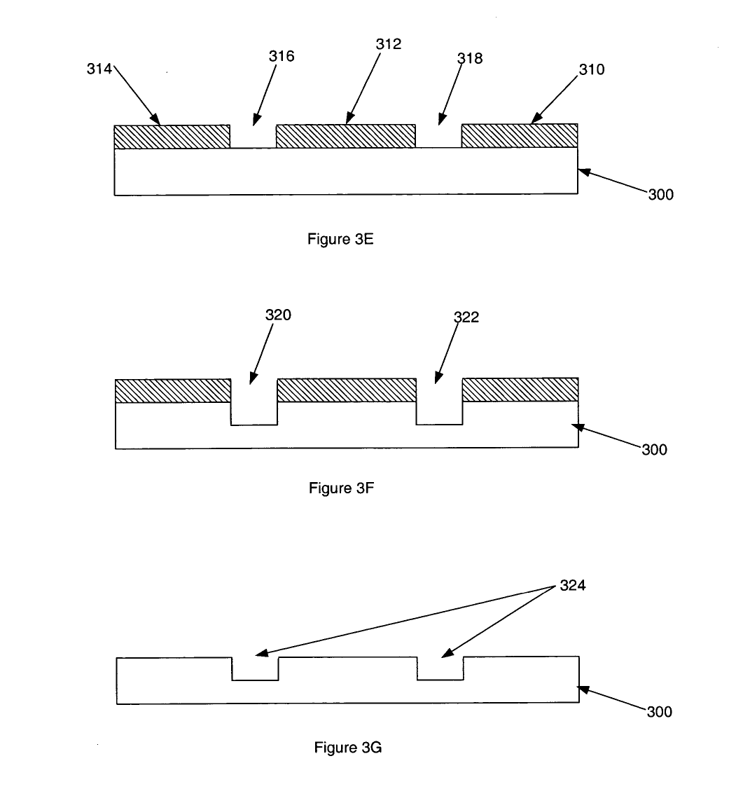

Referring to FIGS. 3A-3G, an embodiment of an inventive substrate patterning flow is depicted in cross sectional views, wherein a resist layer is deposited and patterned before placement of a hardmask layer.

Referring to FIG. 3A, a resist layer (302) is formed adjacent a substrate layer (300). The resist layer (302) may comprise a radiation sensitive resist material, tuned to radiation wavelengths such as 248 nanometers, 193 nanometers, 157 nanometers, and 10-15 nanometers, or sensitive to electron irradiation, which may be appropriate given the requisite geometric scenario, as would be apparent to one skilled in the art. For example, polyhydroxystyrene resists, acrylate resists, and, fluorinated resists are available for such uses from suppliers such as Tokyo Ohka Kogyo, ShinEtsu, and Shipley Corporation. In an embodiment, spin-on varieties of such resist materials are used for process efficiency, geometry, and uniformity reasons. The substrate layer (300) may comprise a substrate material such as silicon, polysilicon, gallium arsenide, indium phosphide, indium antimonide, aluminum, copper, tungsten, silicon dioxide, silicon carbide, silicon nitride, silicon oxynitride, carbon-doped oxide, carbon, polymers, a passive or active device-containing substrate having mixed materials, or other materials.

Referring to FIG. 3B, subsequent to radiation exposure at the appropriate wavelength and introduction of an appropriately paired chemical developing agent, such as 2.38% tetramethyl ammonium hydroxide (“TMAH”), discrete resist portions (304, 306) such as those depicted in FIG. 3B may result. Referring to FIG. 3C, subsequent to formation of the discrete resist layer portions (304, 306), a hardmask layer (308) may be formed adjacent the discrete resist layer portions (304, 306) and exposed portions of the substrate layer (300). The hardmask layer (308) may be deposited using techniques such as physical vapor deposition, chemical vapor deposition, spin coating, or other techniques.

The material selected for the hardmask (308) is chosen to have a different etch rate from the substrate (300) in the etching chemistry selected. For example, a silicon or carbon-doped oxide substrate layer (300) may be paired with a spin-on-glass (“SOG”) silicon oxide hardmask layer (308). In another embodiment, for example, a silicon, silicon dioxide, or carbon-doped oxide substrate layer (300) may be paired with an organic spin-on hardmask layer (308), such as those available from JSR Corporation and Dow Chemical.

In one embodiment, the hardmask layer (308) is formed with sufficient thickness to cover the discrete resist layer portions (304, 306), as shown in the embodiment depicted in FIG. 3C. This facilitates forming a substantially uniform and planar surface through planarization or similar treatment, such as timed etching or “etch endpointing,” to remove excess hardmask layer (308) material, as shown in FIG. 3D. Endpoint etching may be utilized when etch byproducts of the resist material are detected, as would be apparent to one skilled in the art, and endpoint etching may be preferred for preventing localized geometry distortion associated with other more mechanically rigorous planarization techniques. The results of such planarization treatment in the cross-sectional depiction of FIG. 3D are discrete resist portions (304, 306) or “plugs” separated from each other by discrete hardmask layer portions (310, 312, 314).

Referring to FIG. 3E, the exposed discrete resist portions (304, 306) may then be decomposed or dissolved and removed to leave behind trenches (316, 318) through the hardmask material to the substrate layer (300). To facilitate dissolution, the resist portions (304, 306) may be exposed to radiation to promote dissolution in wet chemical etchants such as photoresist developer. The intact discrete hardmask layer portions (310, 312, 314) form a hardmask pattern which may then be utilized to pattern the underlying substrate layer (300) with deepened trenches (320, 322), as shown in FIG. 3F. In an embodiment, the deepened trenches (320, 322) are formed with a substantially anisotropic etching technique, such as dry etching or “reactive ion etching,” followed by introduction of a carrier plasma, such as an oxygen, nitrogen, or hydrogen rich carrier plasma, to remove decomposed material. Subsequent to removal of remaining hardmask material (310, 312, 314) utilizing conventional techniques such as selective wet chemical etching, a patterned (324) substrate layer (300) such as that depicted in FIG. 3G may result.

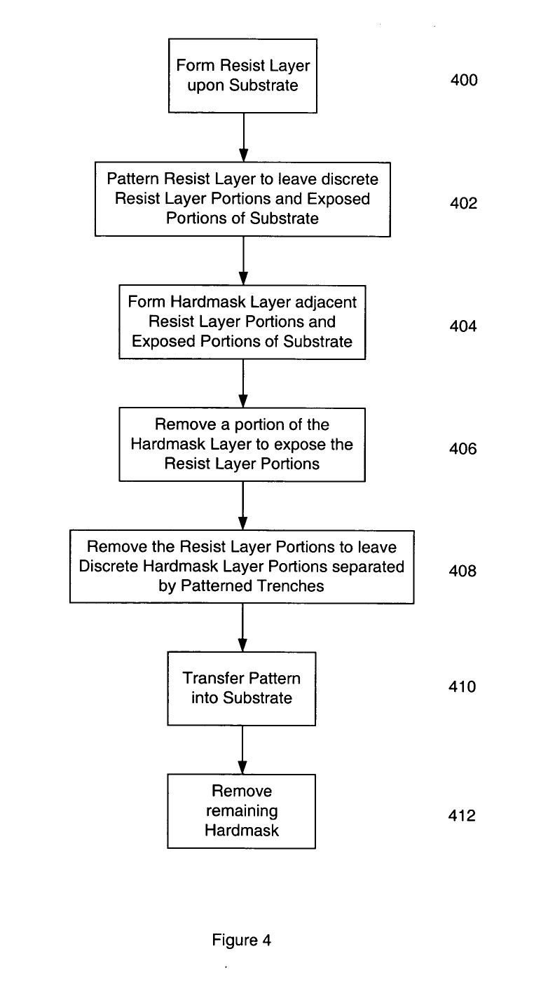

Referring to FIG. 4, an embodiment of the inventive patterning flow, like that depicted in cross-sectional views in FIGS. 3A-3G is summarized in flow chart form. Subsequent to forming (400) a resist layer upon a substrate layer, the resist layer may be patterned (402) to leave discrete resist layer portions and exposed portions of the substrate exposed for further treatment. A hardmask layer may then be formed (404) adjacent the resist layer portions and exposed portions of the substrate layer. The hardmask layer may then be thinned or partially removed (406) to provide access to the discrete resist layer portions, subsequent to which the resist layer portions may be removed (408) to leave discrete hardmask layer portions separated by patterned trenches. Utilizing the patterned trenches as access points to the underlying substrate material, the pattern may be transferred (410) into the substrate. Finally, the remaining hardmask material may be removed (412) to result in a patterned substrate layer.

Because the hardmask layer (308) is formed after resist layer (302) formation and patterning (304, 306), poisoning of unpatterned resist material by adjacently formed hardmask layers is not an issue, and a wider range of hardmask layer (308) materials may be considered, such as amine-containing organic materials for spin-on hardmasking, polyimides, and others. Further, the optical properties of the hardmask are not an issue, since the hardmask layer (308) is formed after resist layer (302) patterning. Resist layer (302) materials having substantially high etch resistances are not required for defining the hardmask patterning and trenching (316, 318). Also, increased lithographic process margin may result from substantially thin resist layers facilitated by pairing a hardmask and hardmask etch chemistry with a relatively high etch selectivity to the substrate. In addition, undesirable etch profile effects, such as “footing” in trenches as described above, may be eliminated.

Thus, a novel substrate patterning solution is disclosed. Although the invention is described herein with reference to specific embodiments, many modifications therein will readily occur to those of ordinary skill in the art. For example, in an embodiment it is desirable to suppress substrate reflection while patterning the photoresist layer (302). To do so, an anti-reflective coating (“ARC”) layer (not shown in the FIGS.) is applied to the substrate layer (300) prior to forming the resist layer (302) on the substrate layer (300). Other embodiments with other modifications will also readily occur to those of ordinary skill in the art. Accordingly, all such variations and modifications are included within the intended scope of the invention as defined by the following claims.

1. A method to pattern a substrate comprising:
a. forming a resist layer adjacent a substrate layer;
b. patterning the resist layer to leave discrete resist layer portions and exposed portions of the underlying substrate layer;
c. forming a hardmask layer adjacent the resist layer portions and exposed portions of the underlying substrate layer;
d. removing a portion of the hardmask layer to expose the resist layer portions;
e. removing the resist layer portions to leave discrete hardmask layer portions separated by patterned trenches, the discrete hardmask layer portions and trenches forming a hardmask pattern; and
f. transferring the hardmask pattern into the underlying substrate layer.

2. The method of claim 1 wherein forming the resist layer comprises spin coating a resist material.

3. The method of claim 1 wherein patterning the resist layer comprises exposing the resist layer to patterned radiation and removing portions of the resist layer subsequent to exposing by introducing a chemical developing agent.

4. The method of claim 1 wherein forming the hardmask layer comprises spin coating a hardmask material or depositing a hardmask material using chemical vapor deposition.

5. The method of claim 1 wherein removing a portion of the hardmask layer comprises introducing a chemical etchant for a period of time.

6. The method of claim 1 wherein removing a portion of the hardmask layer comprises planarizing the hardmask layer.

7. The method of claim 1 wherein removing the resist layer portions comprises introducing a wet chemical agent to decompose the resist layer portions.

8. The method of claim 1 wherein removing the resist layer portions comprises exposing the resist layer portions to radiation to make them soluble in a developer, and introducing said developer to remove the resist layer portions.

9. The method of claim 1 wherein transferring the hardmask pattern comprises introducing a wet chemical agent selective to the substrate layer.

10. The method of claim 1 wherein transferring the hardmask pattern comprises dry etching the underlying substrate layer through the patterned hardmask pattern to form a substrate decomposition from portions of the substrate layer.

11. The method of claim 10 further comprising introducing a carrier plasma to remove the substrate decomposition.

12. The method of claim 2 wherein the resist material comprises a spin-on photoresist material tuned for a radiation wavelength selected from the group consisting of about 248 nanometers, about 193 nanometers, about 157 nanometers, and about 10-15 nanometers.

13. The method of claim 2 wherein the resist layer comprises a spin-on photoresist material sensitive to electron irradiation.

14. The method of claim 1 wherein the substrate layer comprises a material selected from the group consisting of silicon, polysilicon, gallium arsenide, indium phosphide, indium antimonide, silicon dioxide, silicon carbide, silicon nitride, silicon oxynitride, carbon-doped oxide, aluminum, copper, tungsten, carbon, and polymers.

15. The method of claim 4 wherein the hardmask layer comprises a material selected from the group consisting of spin-on glass and spin-on organic material.

16. A method to form a trench in a substrate layer comprising:
a. forming a resist layer adjacent the substrate layer;
b. patterning the resist layer to leave a discrete resist layer portion covering a trench area of the substrate layer, the trench area of the substrate layer being the area in which the trench will be formed, and to expose portions of the substrate layer adjacent to the trench area of the substrate layer;
c. forming, after patterning the resist layer, a hardmask layer covering the exposed portions of the substrate layer;
d. exposing the trench area of the substrate layer by removing the discrete resist layer portion after forming the hardmask layer; and
f. removing material from the exposed trench area of the substrate layer to form the trench.

17. The method of claim 16 wherein the formed hardmask layer also covers the discrete resist layer portion covering a trench area of the substrate layer, further comprising removing a portion of the hardmask layer to expose the discrete resist layer portion.

18. The method of claim 16 wherein the resist layer comprises a spin-on photoresist material sensitive to electron irradiation.

19. The method of claim 16 wherein the hardmask layer comprises a material selected from the group consisting of spin-on glass and spin-on organic material.
